(19) United States
(12) Patent Application Publication
(10) Pub. No.: US 2011/0068955 A1
(43) Pub. Date: Mar. 24, 2011

(54) Virtual image labeling of input devices

(76) Inventor: Everett Simons, Arlington, VA (US)

(21) Appl. No.: 12/586,423

(22) Filed: Sep. 22, 2009

(51) Int. Cl. H03M 11/00

(52) U.S. Cl. 341/22

(57) ABSTRACT

Partial reflection of an image source creates a virtual image that appears superimposed on a keyboard. This virtual image contains labels for the keys. When users place their hands on the keyboard, this blocks the view of some of the keys but does not block the user's view of the virtual image. This creates a visual perception that users can see the key labels through their own hands. The physical keys themselves may be blank, with the labels existing solely as part of the virtual image. Modifying the image source allows the keyboard to be remapped in a variety of different ways, e.g., switching between Latin and Cyrillic characters, displaying application-specific functions, or remapping keys in a password entry system to prevent an observer from identifying the values of the keys being pressed by the user.

### FIELD OF THE INVENTION

The invention relates to user interfaces that allow manual input to electronic devices.

### DESCRIPTION OF RELATED ART

A computer keyboard typically includes an array of character keys, usually labeled with either one character, such as a letter, or two characters, such as a colon and a semi-colon. Pressing a character key typically generates a character value associated with the character key. Computer keyboards typically include control keys, such as “Shift”, “Ctrl”, and “Alt”, that can modify the effect of pressing a character key. For example, pressing the “Shift” key concurrently with an alphabetical character key capitalizes the character. A computer keyboard usually has an array of function keys associated with various purposes; these purposes may vary among applications.

A touchpad is an input device that allows an electronic system to detect where a user's finger and/or a stylus has made contact with the input device.

A numeric keyboard typically includes an array of number keys, and often contains one or more special keys such as “*” and “#”. A numbered key may also be labeled with one or more letters, such as a telephone “2” key also displaying “abc”.

### BRIEF SUMMARY OF THE INVENTION

One embodiment uses a keyboard, an image source above the keyboard, and a transparent plate midway between the keyboard and the image source. The plate creates a partial reflection of the image source; this reflection is called a “virtual image”. A user observing the keyboard through the plate also sees the virtual image of the image source, apparently at the same location as the keyboard. The actual keys on the keyboard may be blank, with the key labels existing solely within the virtual image.

When the user's hands are not on the keyboard, the user perceives a keyboard with labeled keys. Because the virtual image containing the key labels is created by a reflection from above the plate, nothing below the plate blocks the user's view of the key labels. Therefore, when the user's hands are operating the keyboard, the hands do not block the reflection, and the virtual image containing the key labels remains visible. Users thus have the visual perception of being able to see the key labels through their own hands. This allows the desired key to be identified without requiring users to move their hands out of the way.

The image source can be electronically changed in response to user actions. For example, a single key can display “@” above “2” with the “2” emphasized under default conditions and the “@” emphasized when the “Shift” key is pressed. The image may also be customized for particular applications. For example, pressing the control key, “Ctrl”, can cause the various character key labels to display their associated functions, such as the “C” character key displaying “copy” to indicate the function that would be activated by pressing the combination of the “Ctrl” key and the “C” key simultaneously.

### BRIEF DESCRIPTION OF THE SEVERAL VIEWS OF THE DRAWINGS

FIG. 1 illustrates a profile view of an embodiment where a screen of a laptop computer provides an image source, and a plate reflects the image source to create a virtual image of a keyboard that appears to the user to be in the same location as the actual laptop keyboard.

FIG. 2 illustrates a reversed image of the keyboard as it exists on the image source in FIG. 1; the virtual image created by a reflection of this pattern in the plate reads correctly.

FIG. 3 illustrates a profile view of an embodiment where the virtual image only spans the rear of the keyboard.

FIG. 4 illustrates a profile view of an embodiment where the source of the virtual image is above the screen of a computer.

FIG. 5 illustrates a cut-away profile view of an embodiment where two image sources are to the right and left of a keyboard, and virtual images are created by two reflective plates.

FIG. 6. illustrates a profile view of an embodiment where the image source is roughly parallel to the user's direct line of sight.

### DETAILED DESCRIPTION

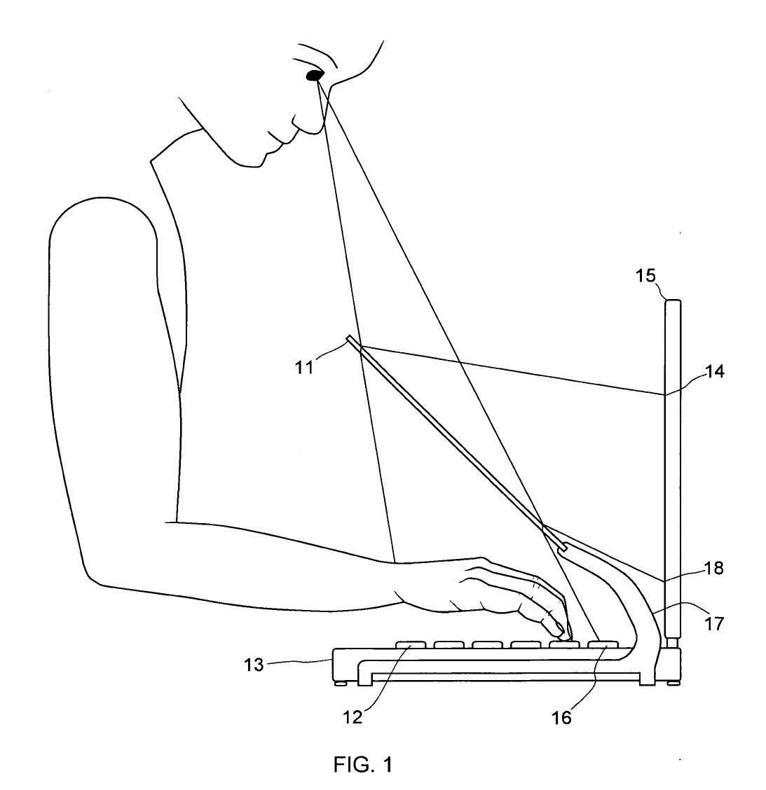

In the embodiment shown in FIG. 1, plate 11 is held over keyboard 13 by bracket 17.

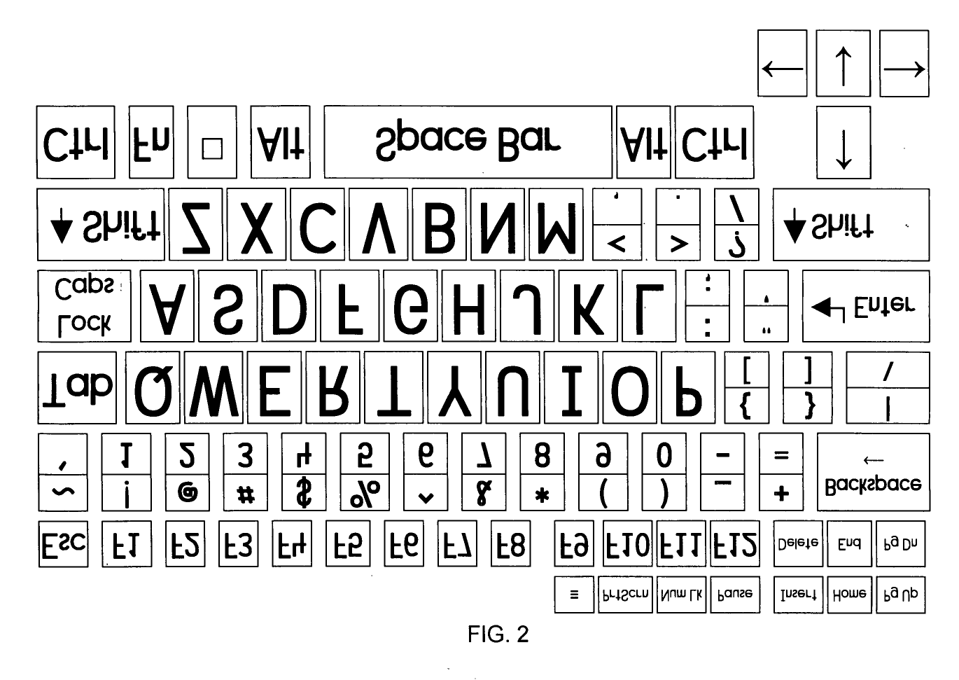

Plate 11 may, for example, be glass, with the surface towards the keyboard 13 having an anti-reflective coating on the lower surface. Plate 11 can have a surface with enhanced reflectivity, such as partial mirroring, preferably on the top surface. An image source 15 depicts a mirror image of the keyboard 13; this image, illustrated in FIG. 2, is reflected by plate 11. The user perceives the reflected image of the image source 15 to be about in the same plane as the keyboard 13. The user's hands can be placed between the plate 11 and the keyboard 13 and block at least part of the user's view of the actual keyboard 13 without blocking the user's view of the reflected image of the image source 15.

In FIG. 1, the user can see a rear key 16 through the plate 11; the user can also see a virtual image of lower location 18, apparently in the same location as the rear key 16. For example, when the rear key 16 is a solid black key, and the lower location 18 on the image source 15 shows a reversed character in a bright font on a dark background, a virtual image of that character appears to be on the rear key 16, and the virtual image appears right side up.

When a user's hand is placed onto the keyboard, as shown in FIG. 1, the image of near key 12 is blocked, but the virtual image of an upper location 14 is still visible. When the virtual image of the upper location 14 contains an inverted character label for the near key 12, the virtual image of the character at upper location 14 appears to exist where the near key 12 is located, independent of whether the user's hand blocks the user's view of the actual near key 12. Upper location 14 may also contain an approximate outline of near key 12.

When the image source 15 has an array of inverted characters such that the virtual images of these characters appears to label the keys on the keyboard 13, the aggregate perception is that the keys themselves are labeled, and that these labels can be seen through the user's hands. A separate monitor (not shown) was used to display the applications.

Because the key images can be electronically generated and visually super-imposed on the keys, the keys can be remapped in response to the user's input. For example, pressing the control key, “Ctrl”, can cause the “C” key label to instead read as “copy”. This is particularly helpful for an infrequent user, or for programs with numerous keyboard shortcuts.

The key images may also show more than one label, and change which one is highlighted. For example, a key can display “@” above “2” with the “2” highlighted under default conditions and the “@” highlighted when the “Shift” key is pressed. Thus, the user sees how the effect of pressing a particular key changes when one or more control keys are pressed.

In this embodiment, the reflective surface was at a predetermined angle to the keyboard, and the image plane adjusted to align the virtual image plane to the keyboard. The reflective surface may also be articulated, such that it continues to approximately bisect the keyboard and image planes as they are adjusted relative to each other. A laptop computer can include a sensor to detect whether the reflector is present, and generate an image source accordingly. Such a sensor could, e.g., be optical, mechanical, electrical, or magnetic.

FIG. 2 shows a reversed image of a keyboard as it appears on the image source. One embodiment used a virtual image with a size 72 font for the single character keys, such as the letters, and size 24 to 36 fonts for the double-character keys, e.g. the “&” displayed above the “7”, one or the other of which can be visually highlighted depending upon whether the “Shift” key is pressed. Highlighting which of two characters is currently enabled can be helpful even for the reasonably adept keyboard user, because of the infrequency with which some of the keys with shared characters are used, such as the key with both “[” and “{”. To make the user's hands more visible, such as for a person just learning to type, the labels on the image source can use a black background with bright letters. Separate illumination for the user's hands can also be provided and controlled. To make the user's hands less visible, a white background with black letters such as shown in FIG. 2 was effective. A bright background with characters in a bright contrasting color was also able to de-emphasize the user's hands.

The physical keys need not be labeled. A keyboard with unlabeled black keys provided the best image background. The character set of the virtual image can be altered by the control system. For example, a Cyrillic or Greek alphabet can be selected, or mathematical symbols can be displayed; pictographic symbols can also be used.

Pressing control keys can allow special functions to appear at the locations of the associated keys. For example, in a typical text editor, pressing the “Ctrl” key” causes the “C” character key to have the function “copy” and the “V” character key to have the function “paste”. Pressing the “Ctrl” key can cause the control system to display the applicable functions in lieu of the characters. Different software packages can have different sets of functions incorporated into the virtual images generated by the software. The virtual labels of these special functions can be muted or absent by default, and highlighted when the associated control key is pressed. This allows the appearance of the input device to reflect changes in how an input activation will be interpreted.

There are several ways to use embodiments of the present invention as a learning tool. Images of individual keys can be highlighted for the user to press, allowing beginners to improve basic coordination before mastering touch-typing. Proper typing habits can be emphasized by displaying arrows from the “home” keys to the other keys that should be typed with the same finger; e.g., a line or arrow from “J” to “U”. Key images can react to being pressed by the user; changing the hue was particularly effective for emphasizing which key had been pressed.

Without the need for discrete labeling of the keys, the keyboard can be replaced by a touch pad, such that the locations of the finger strikes are measured. This can allow different virtual keyboards to be displayed and used, not just by altering the virtual labels on existing discrete keys, but by actually remapping the “key” input locations themselves. The total number of input locations can thus be varied, depending upon the requirements of the particular character set, how many special functions are desired, etc. The fingers need not even make contact with a physical object when entering data: finger locations may be sensed optically or electronically, e.g. with a capacitive sensor.

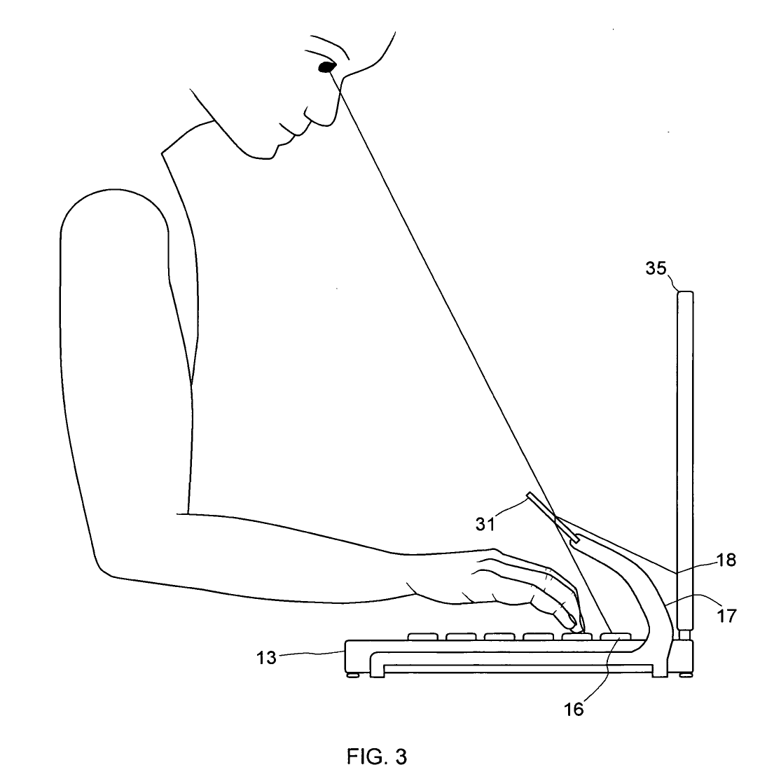

FIG. 3 shows an embodiment where the virtual image does not span the entire keyboard. A narrow plate 31 held by bracket 17 reflects the lower edge of a screen 35 to create a virtual image limited to the rear of keyboard 13. The user sees rear key 16 through plate 31; the user also sees a virtual image of lower location 18, apparently in the same location as rear key 16. Practical advantages to this arrangement include the typical placement of function keys along the rear of keyboard. This embodiment relaxes the requirement for co-planarity between the virtual image and the physical input device, and leaves the majority of screen 35 available for conventional use.

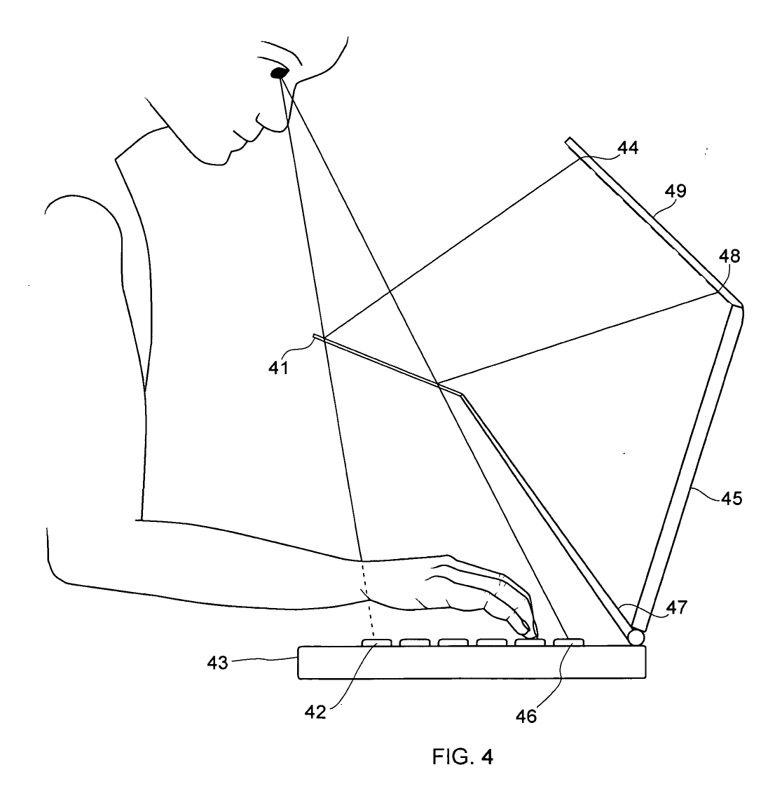

The embodiment shown in FIG. 4 had a screen 45 and a separate image source 49. Plate 41, held in place by bracket 47, created a virtual image of the image source 49 in the plane of a keyboard 43. Thus, a key label at location 48 on image source 49 appeared to exist on a key 46; a key label at location 44 on image source 49 appeared to exist at the location of key 42, even though the user's view of the actual key 42 was blocked by the user's hand. Neither image source 49 nor reflective plate 41 impeded the user's view of screen 45. In this embodiment, the angle between the reflective plate 41 and the keyboard 43 was about 20 to 25 degrees.

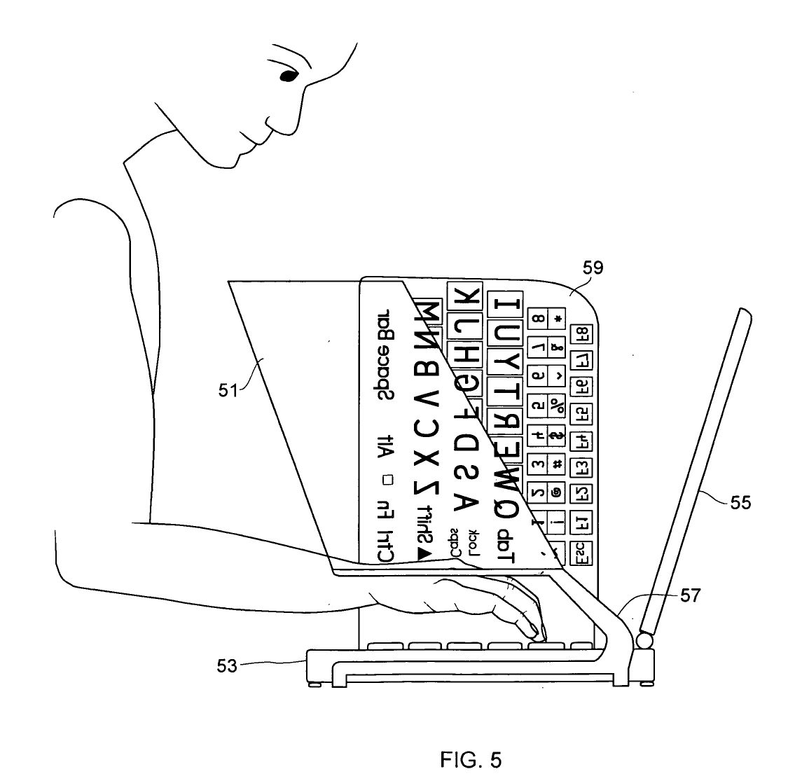

In the embodiment shown in FIG. 5, two reflective plates were used, approximately perpendicular to each other, with each plate at about a 45 degree angle to the keyboard. Plate 51 was to the user's right, held in place by bracket 57; the other reflective plate, to the user's left, is omitted from the illustration for clarity. From the user's orientation, these two plates were symmetrical, to the right and left, with the top edges meeting along a common line. Two image sources were used, one to the left and one to the right of the user, each image source being approximately vertical. The two image sources were thus parallel and facing each other. Image source 59 shown in FIG. 5 was to the left of the user; the image source to the right of the user has been omitted from the illustration for clarity. In this view, a portion of left image source 59 is behind plate 51. For purposes of illustration only, the portion of left image source 59 behind plate 51 is depicted with the outlines of the keys removed, but with the key images themselves unchanged.

In this embodiment, keyboard 53 and screen 55 were both part of a conventional laptop computer; neither plate 51 nor image source 59 interfered with the user's view of the screen 55 of the laptop computer, or with access to the keyboard 53. The working area of each reflective surface was roughly a trapezoid. The virtual image caused by the reflection of image source 59 spanned the entire left half of the keyboard and extended beyond the midline, to create some overlap with the virtual image formed by reflection the omitted image source in plate 51. Each of the left and right image sources provided somewhat more than their respective halves of the virtual image, creating an overlapping of the two virtual images along the midline of the keyboard, to accommodate offsets from the midline of the user's line of sight.

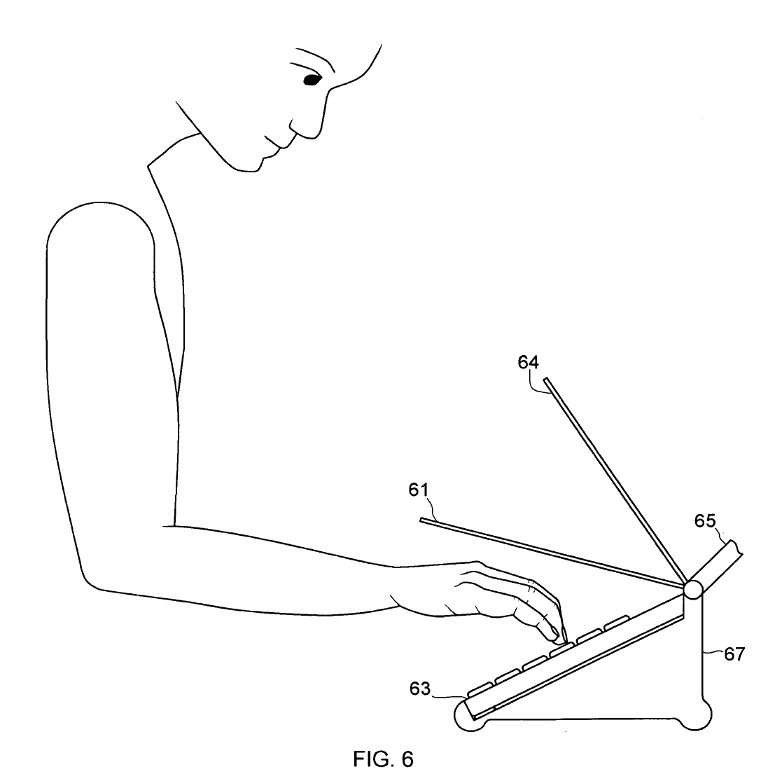

The embodiment shown in FIG. 6 used a keyboard 63 and screen 65 of a conventional laptop computer to control and display the software applications being run. Image source 64 was reflected in plate 61 to create a virtual image that appeared in the plane of the keyboard 63. In this embodiment, image source 64 was oriented roughly parallel to the line of sight of the user, and did not block the view of the screen 65 or the view of the keyboard 63.

Some embodiments used glass as the reflective plate; others used plastic, such as polycarbonate. Including an anti-reflective coating on the lower surface reduced unwanted secondary reflections: a 0.02-0.04 mm layer of low density polyethylene was sufficient to reduce secondary reflections from the lower surface of a glass plate. Other embodiments used a plastic plate with a reflective coating on the first (top) surface. For some purposes, such as training users to “touch-type” without looking at their hands, the reflective surface need not transmit much if any light from the user's hands.

Virtual labeling can be used to enhance the security of password entry systems by using blank keys. The actual mapping of characters onto keys need not be readily visible to anyone other than the user. A password entry routine can remap some or all of the keys; such remapping can be systematic or random. A bystander able to see the keys but not their virtual labels would thus have no means for determining the character values associated with the keys being pressed. Narrow viewing angle image sources could be used for this type of application.

Polarization of the image source may impact the reflected image, especially if the reflective surface is unmirrored and is at or near the Brewster angle, typically 54 to 63 degrees, with respect to the image source. In such cases, proper orientation of the image source polarization may be critical. In systems where the image source is a nematic display used solely to create a virtual image, this effect may be used advantageously to dispense with the exiting polarizer, as this function will be performed by the reflection, or lack thereof, at the Brewster angle.

The image source need not be planar. For example, if an ergonomically contoured keyboard is used, the image source could be a three-dimensional “mirror image” of the contoured keyboard, with the virtual images of reversed character labels on the display appearing at the heights of the various keys in the keyboard, even though the keys are not all in the same plane.

What is claimed is:

1. An apparatus comprising:
an electronic input device at a first location;
a correlated image source at a second location different from the first location; and
a reflective surface that creates a virtual image of the image source,
whereby the virtual image of the image source appears to be in the first location.

2. The apparatus of claim 1,
wherein the input device is a keyboard.

3. The apparatus of claim 2, additionally comprising:
a controller adapted to modify a visible attribute of the image source in response to a user input.

4. The apparatus of claim 3, wherein:
the keyboard comprises a control key; and
the user input comprises activation of the control key.

5. The apparatus of claim 3, wherein:
the keyboard comprises a character key; and
the user input comprises activation of the character key.

6. The apparatus of claim 3,
wherein the controller is adapted to enable the image source to depict different character sets.

7. The apparatus of claim 1,
wherein the input device is a touch pad.

8. The apparatus of claim 7, additionally comprising:
a controller adapted to modify the appearance of the image source in response to a user input.

9. A method for labeling an input device with a virtual image of a correlated image source, comprising the steps of:
transmitting light from the input device, and
reflecting light from the image source,
whereby the virtual image of the image source appears to be superimposed on the input device.

10. The method of claim 9,
wherein the virtual image includes a character label.

11. The method of claim 9,
wherein the virtual image includes a function label.

12. The method of claim 9, additionally comprising:
modifying the virtual image to indicate a change in interpretation of input device actuation.

13. The method of claim 9, additionally comprising:
modifying the virtual image in response to a signal from the input device.

14. The method of claim 13,
wherein the step of modifying the virtual image comprises highlighting a portion of the input device that has been activated by the user.

15. The method of claim 13,
wherein the step of modifying the virtual image comprises indication of a change in functionality of the input device.

16. A computer program product, tangibly embodied in a machine-readable medium, the computer program product comprising instructions that, when read by a machine, operate to cause data processing apparatus to performs the steps of:
generating a display image, a virtual image of which comprises labels correlated to a manual input device;
receiving a signal from the manual input device; and
modifying the display image in response to the signal.

17. The computer program product of claim 16,
wherein the step of modifying the display image comprises indication of a change in functionality of at least a portion of the manual input device.

18. The computer program product of claim 16,
wherein the step of modifying the display image comprises a remapping of at least a portion of the manual input device.

19. The computer program product of claim 16,
wherein the step of modifying the display image comprises a change in character set.

20. The computer program product of claim 16,
wherein the step of modifying the display image comprises highlighting a portion of the manual input device in response to user actuation of the portion.
